(19) United States
(12) Patent Application Publication
(10) Pub. No.: US 2008/0073732 A1
(43) Pub. Date: Mar. 27, 2008

(54) METHOD OF MANUFACTURING SEMICONDUCTOR DEVICE

(76) Inventor: Sung-Joong Joo, Incheon (KR)

Correspondence Address: SHERR & NOURSE, PLLC, 620 HERNDON PARKWAY, SUITE 200, HERNDON, VA, 20170, US

(21) Appl. No.: 11/852,029

(22) Filed: Sep. 7, 2007

(30) Foreign Application Priority Data
Sep. 22, 2006 (KR) 10-2006-0092093

(51) Int. Cl. H01L 29/78; H01L 21/336

(52) U.S. Cl. 257/410; 438/287; 257/E21.409; 257/E29.255

(57) ABSTRACT

Embodiments relate to a method of manufacturing a semiconductor device, which may facilitate high integration of the device and may prevent undercut form occurring. In embodiments, the method may include forming a gate insulating film on a semiconductor substrate, forming, on the gate insulating film, a gate electrode having a spacer formed on both sidewalls thereof, forming a source/drain region in regions of the substrate located at both sides of the gate electrode, forming a non-salicide film on the entire surface of the substrate, performing a wet process and a pre-cleaning process with respect to a region of the non-salicide film in which a salicide film will be formed, forming the salicide film on the gate electrode and the source/drain region, and performing a primary annealing process, a wet etching process, a secondary annealing process with respect to the salicide film.

The present application claims priority under 35 U.S.C. 119 and 35 U.S.C. 365 to Korean Patent Application No. 10-2006-0092093 (filed on Sep. 22, 2006), which is hereby incorporated by reference in its entirety.

### BACKGROUND

As semiconductor devices become more highly integrated, a design rule may be reduced and an operation speed may be increased. Moreover, a size of a gate electrode of a transistor may be reduced. Thus, sheet resistance and contact resistance increase, which may be problematic.

To solve such problems, a technology for forming silicide having a high-melting-point metal and low specific resistance on a silicon substrate with a gate electrode formed of a polysilicon layer and a source/drain region has been developed. As a result, the resistance of the gate electrode and the contact resistance of the source/drain region were reduced.

Initially, a process of forming silicide on the gate electrode and a process of forming silicide on the source/drain region may have been performed separately. However, to simplify the process and reduce costs, a self aligned silicide (salicide) process for forming silicide on a gate electrode and a source/drain region through the same process was developed.

In the salicide process, if a high-melting-point metal is simultaneously laminated on a silicon layer and an insulating layer and is annealed, a silicide reaction may occur in the high-melting-point metal on the silicon layer to form a silicide layer. However, silicide reaction may not occur in the high-melting-point metal on the insulating layer and thus the high-melting-point metal may remain without alteration.

Therefore, to leave only the silicide layer, the unreacted high-melting-point metal may be selectively etched and removed.

Meanwhile, an interlayer insulating film may be laminated in a non-salicide region to prevent electrostatic discharge of the semiconductor device and resistance. The interlayer insulating film may be used to prevent a high-melting-point metal layer for a salicide layer from being deposited on the silicon layer of the source/drain region and the gate electrode of the transistor.

As the salicide process may be applied to the manufacturing of a transistor, the salicide process may be replaced with a salicide forming process using a known chemical vapor deposition method.

For example, a titanium silicide film (TiSi₂) or a tungsten silicide film (WSi₂) may be used as a silicide film. However, in a logic device having a gate length of 90 nm or less or a merged DRAM on logic (MDL) device including a combination of a logic and a DRAM, a cobalt silicide film (CoSi₂) having line width dependence and thermal stability may have been used to improve capability of the device. That is, a salicide process using a cobalt silicide film may be widely being used in a process of manufacturing a transistor.

A related art semiconductor device manufacturing method for forming salicide will now be briefly described.

A gate insulating layer may be formed on a substrate in which a device isolation film may be formed. A material layer for forming a gate electrode, such as polysilicon, may be deposited on the gate insulating layer.

Subsequently, the deposited polysilicon layer may be selectively patterned to form a gate electrode layer.

A material layer for forming a sidewall layer, such as a CVD oxide film or nitride film, may be deposited on the entire surface of the semiconductor substrate on which the gate electrode layer may be formed and may be etched to form the gate sidewall layer on the side surface of the gate electrode layer. At this time, in the etching process for forming the gate sidewall layer, overetching may occur such that the silicon (Si) formed on the gate electrode and a region in which a source/drain region will be formed may be damaged.

Thereafter, the source/drain region may be formed using an ion implantation method. Subsequently, a Co layer, a Ti layer and a TiN layer may be sequentially deposited on the entire surface of the substrate including the gate electrode layer, in order to a salicide layer.

Thereafter, a CoSi layer may be formed using a primary annealing process, the unreacted Co layer and Ti layer may be removed using a wet process, and a cobalt salicide layer may be formed using a secondary annealing process.

However, as shown in FIG. 1, when the cobalt salicide is wet-etched after the oxide film for the gate sidewall layer may be etched to form the gate sidewall layer, undercut of salicide may occur.

A thickness of the salicide formed on the gate electrode may be twice that of salicide of the existing 130-nm device. As a semiconductor device has been downsized, a junction thickness and a width of a gate electrode may be gradually reduced. If the existing 130-nm salicide process is used in a sub-90-nm process, the thickness of the salicide may increase excessively and a shallow junction may be broken down. Thus, problems such as junction leakage current and contact resistance may occur.

### SUMMARY

Embodiments relate to a semiconductor device and a method of manufacturing a semiconductor device. Embodiments relate to a method of manufacturing a semiconductor device, which may be capable of facilitating high integration of the device while preventing undercut from occurring.

Embodiments relate to a semiconductor device and a method of manufacturing a semiconductor device, which may be capable of preventing silicon on a gate electrode and a source/drain region from being overetched, which may prevent undercut from occurring and may reduce a depth of a salicide film for high integration of devices.

According to embodiments, a method of manufacturing a semiconductor device may include forming a gate insulating film on a semiconductor substrate, forming, on the gate insulating film, a gate electrode having a spacer formed on both sidewalls thereof, forming a source/drain region in regions of the substrate located at both sides of the gate electrode, forming a non-salicide film on the entire surface of the substrate, performing a wet process and a pre-cleaning process with respect to a region of the non-salicide film in which a salicide film will be formed, forming the salicide film on the gate electrode and the source/drain region, and performing a primary annealing process, a wet etching process, a secondary annealing process with respect to the salicide film.

### DRAWINGS

FIG. 1 is a cross-sectional view illustrating a resultant semiconductor device obtained after performing a related art salicide process.

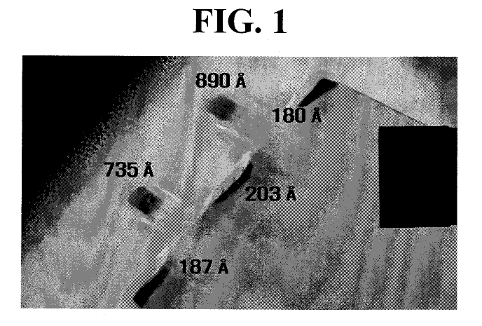

FIG. 2 is a flowchart illustrating a method of manufacturing a semiconductor device including a salicide process according to embodiments.

FIG. 3 is a cross-sectional view illustrating a resultant semiconductor device after performing a salicide process according to embodiments.

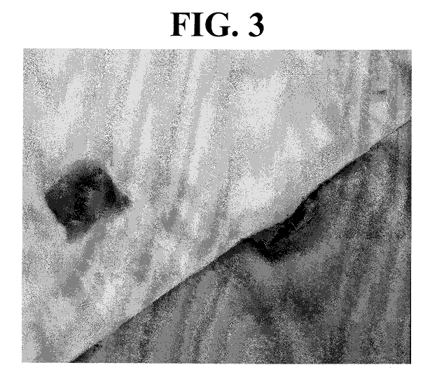

### DESCRIPTION

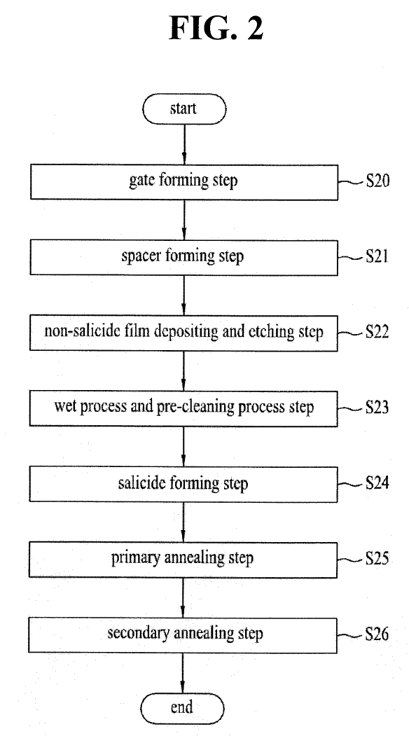

FIG. 2 is a flowchart illustrating a method of manufacturing a semiconductor device according to embodiments.

Referring to FIG. 2, an insulating layer may be formed in a field region of a semiconductor substrate and may define an active region of the semiconductor substrate. For example, a silicon oxide film may be formed in the field region of the substrate as the insulating layer. The semiconductor substrate may be, for example, a P-type or N-type single-crystal silicon substrate.

According to embodiments, the insulating layer may be formed using a shallow trench isolation (STI) process or a local oxidation of silicon (LOCOS) process.

A gate insulating film, such as an oxide film, may be grown on the active region of the substrate by a thermal oxidation process, and a gate electrode pattern may be formed on a portion of the gate insulating film in order to form a gate electrode (S20). In embodiments, a conductive layer for the gate electrode, such as a polysilicon layer, may be laminated on the substrate including the gate insulating film with a predetermined thickness. Subsequently, the gate electrode pattern may be formed on only a portion of the gate insulating film using a photolithography process.

Next, a spacer may be formed on both sidewalls of the gate electrode (S21). To form the spacer, an oxide-nitride-oxide (ONO) film for the spacer may be laminated on the substrate and the gate electrode and the gate insulating film, and may be etched by an etch-back process having an anisotropic etching characteristic. The etching may continue until the gate electrode, that is, the polysilicon layer, and the gate insulating film are exposed. Accordingly, the gate electrode having the spacer formed at both sidewalls thereof may be formed.

According to embodiments, if the ONO film is etched to form the spacer, an overetching process may be avoided and may prevent silicon (Si) on the gate electrode formed previously and the source/drain region which will be formed by a subsequent process from being damaged. Accordingly, it may be possible to suppress undercut which may occur in a subsequent salicide wet process.

A non-salicide film may be deposited on a surface, for example the entire surface, of the substrate on which the gate electrode having the spacer may be formed. Thereafter, a portion of the non-salicide film in which a salicide film will not be formed may be subjected to an etching process (S22). In embodiments, a portion of the non-salicide film, excluding a region in which the salicide film will be formed, may be etched.

According to embodiments, the non-salicide film may be formed on the gate electrode and the source/drain region, i.e., in a region in which the salicide film will be formed.

When the non-salicide film is formed before the subsequent process for forming the salicide film, a shallow salicide film may be formed even in a sub-90-nm process. Hence, problems such as junction leakage current and contact resistance may be solved.

To form the salicide film, a wet process and a pre-cleaning process may be performed with respect to a resultant material, for example using a HF solution to perform a process of removing a natural oxide film (S23).

When the wet process is performed, undercut may not occur due to the non-salicide film formed on the gate electrode and the source/drain region.

To form the salicide film on the substrate including the resultant material, a Co film, a Ti film, and a TiN film may be sequentially formed (S24). In embodiments it may be preferable that a thickness of the Co film be 110 to 130 Å, a thickness of the Ti film be 190 to 210 Å, and a thickness of the TiN film be 210 to 230 Å.

The Ti film may be used as a film for blocking an influence of oxygen when Co and Si react with each other by an annealing process and may be used to control the reaction between Co and Si. According to embodiments, if the thickness of the Ti film is significantly larger than that of the other films, sheet resistance Rs may increase. According to embodiments, it may be preferable that the Tin film be formed with a predetermined small thickness.

The processes of forming the Ti film and the TiN film may be continuously performed in the same deposition chamber or may be separately in different deposition chambers.

A primary annealing process may be performed with respect to the resultant material and may selectively form a CoSi layer on surfaces of the gate electrode and the source/drain region (S25). In embodiments, the primary annealing process may be preferably performed at a temperature of approximately 400 to 500° C. After the primary annealing process, the unreacted Co film, Ti film and TiN film may be sequentially removed. According to embodiments, the Co film and Ti film which do not react by the spacer may be removed by a wet etching process using an etchant. A secondary annealing process may be performed with respect to the resultant material and may selectively form a cobalt silicide layer on the surfaces of the gate electrode and the source/drain region (S26). According to embodiments, it may be preferable that the secondary annealing process be performed at a temperature of approximately 700 to 900° C.

According to embodiments, it may be possible to prevent silicon on a gate electrode and a source/drain region from being overetched, which may prevent undercut from occurring.

The depth of a salicide film for high integration of the device may be reduced by forming a non-salicide film before forming the salicide film. Accordingly, even in a sub-90-nm device, a reliable salicide process can be performed.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A method, comprising:
forming a non-salicide film over a surface of a semiconductor substrate, the semiconductor substrate including a gate electrode over a gate insulating film and spacers on each sidewall of the gate electrode;
performing a wet process and a pre-cleaning process in a first region of the non-salicide film;
forming a salicide film over the gate electrode and the source/drain region in the first region of the non-salicide film; and
performing a primary annealing process, a wet etching process, and a secondary annealing process with respect to the salicide film.

2. The method of claim 1, wherein the non-salicide film is formed over an entire surface of the substrate

3. The method of claim 1, further comprising etching a portion of the non-salicide film excluding the first region of the non-salicide film in which the salicide film will be formed.

4. The method of claim 1, further comprising:
forming the gate insulating film over the semiconductor substrate;
forming the gate electrode over the gate insulating film;
forming a spacer on each sidewall of the gate electrode; and
forming a source/drain region in regions of the substrate located at both sides of the gate electrode.

5. The method of claim 4, wherein the spacer is formed over the gate electrode by forming an oxide-nitride-oxide (ONO) film over the surface of the substrate on which the gate electrode is formed and etching the ONO film until the gate insulating film and the gate electrode are exposed.

6. The method of claim 5, wherein the ONO film is laminated and formed using a chemical vapor deposition process.

7. The method of claim 5, wherein the ONO film is etched using an etch-back process having an anisotropic etching characteristic.

8. The method of claim 1, wherein the salicide film comprises at least one of a Co film having a thickness of 110 to 130 Å, a Ti film having a thickness of 190 to 210 Å, and a TiN film having a thickness of 210 to 230 Å.

9. The method of claim 1, wherein the primary annealing process is performed at a temperature of 400 to 500° C.

10. The method of claim 1, wherein the secondary annealing process is performed at a temperature of 700 to 900° C.

11. A device, comprising:
a gate insulating film over a semiconductor substrate;
a gate electrode over the gate insulating film,
sidewalls formed on both sides of the gate electrode;
a source/drain region in regions of the substrate located at both sides of the gate electrode; and
a salicide film over the gate electrode and the source/drain region, wherein the salicide film is formed by
forming a non-salicide film over a surface of the substrate;
performing a wet process and a pre-cleaning process in a first region of the non-salicide film;
forming a salicide film over the gate electrode and the source/drain region in the first region of the non-salicide film; and
performing a primary annealing process, a wet etching process, and a secondary annealing process with respect to the salicide film.

12. The device of claim 11, wherein a portion of the non-salicide film excluding the first region of the non-salicide film in which the salicide film will be formed is etched.

13. The device of claim 12, wherein the spacer is formed over the gate electrode by forming an oxide-nitride-oxide (ONO) film over the surface of the substrate on which the gate electrode is formed and etching the ONO film until the gate insulating film and the gate electrode are exposed.

14. The device of claim 13, wherein the ONO film is laminated and formed using a chemical vapor deposition process.

15. The device of claim 13, wherein the ONO film is etched using an etch-back process having an anisotropic etching characteristic.

16. The device of claim 12, wherein the salicide film comprises at least one of a Co film having a thickness of 110 to 130 Å, a Ti film having a thickness of 190 to 210 Å, and a TiN film having a thickness of 210 to 230 Å.

17. The device of claim 12, wherein the primary annealing process is performed at a temperature of 400 to 500° C.

18. The device of claim 12, wherein the secondary annealing process is performed at a temperature of 700 to 900° C.
